(19) United States
(12) Patent Application Publication
(10) Pub. No.: US 2009/0015148 A1
(43) Pub. Date: Jan. 15, 2009

(54) DISPLAY DEVICE

(76) Inventor: Jun HANARI, Fukaya-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/146,773

(22) Filed: Jun. 26, 2008

(30) Foreign Application Priority Data
Jul. 13, 2007 (JP) 2007-184242

(51) Int. Cl. H01L 51/50; H01J 1/62

(52) U.S. Cl. 313/504; 313/506

(57) ABSTRACT

A display device includes an array substrate which includes, in an active area of a wiring substrate, a self-luminous element provided in each of matrix-arrayed pixels, and a partition wall separating the pixels. The array substrate further includes a support member which is isolated from the self-luminous element and has a predetermined height from a major surface of the wiring substrate.

### CROSS-REFERENCE TO RELATED APPLICATIONS

This application is based upon and claims the benefit of priority from prior Japanese Patent Application No. 2007-184242, filed Jul. 13, 2007, the entire contents of which are incorporated herein by reference.

### BACKGROUND OF THE INVENTION

1. Field of the Invention

The present invention relates generally to a display device, and more particularly to a display device having a self-luminous element including a thin film which is formed through an evaporation deposition step via an evaporation deposition mask having a predetermined aperture pattern.

2. Description of the Related Art

In recent years, organic electroluminescence (EL) display devices have attracted attention as flat-panel display devices. Since the organic EL display device includes an organic EL element which is a self-luminous element, it has such features as a wide viewing angle, small thickness and light weight without a need for backlight, low power consumption, and a high responsivity speed. For these features, attention has been paid to the organic EL display device as a promising candidate for the next-generation flat-panel display device, which will take the place of liquid crystal display devices.

The organic EL element, together with a pixel circuit, etc., is provided on an array substrate, and is configured such that an organic active layer containing an organic compound with a light-emitting function is held between an anode and a cathode. However, materials which are used for the organic EL element, in particular, materials which form the organic active layer, include a material which easily deteriorates due to moisture or oxygen. Thus, the organic EL element is airtightly sealed in an inert gas atmosphere or in a vacuum by a sealing substrate which is disposed to be opposed to an array substrate.

The organic EL display devices are classified into a bottom emission type in which light that is generated from the organic EL element is extracted to the outside from the array substrate side, and a top emission type in which light that is generated from the organic EL element is extracted to the outside from the sealing substrate side.

In the manufacturing process of the organic EL element, an evaporation deposition method, in which a material source that is dispersed from an evaporation deposition source, is deposited by evaporation, is applicable to a fabrication step of forming an organic active layer that is formed of a low-molecular-weight organic compound (see, e.g. Jpn. Pat. Appln. KOKAI Publication No. 2004-323888).

In a typical method for providing an organic EL display device which is capable of color display, for example, a plurality of kinds of color pixels, which emit red (R), green (G) and blue (B) lights, are disposed. An applicable method of forming an organic active layer (in particular, a light-emitting layer), which is disposed in each of the color pixels, is a mask evaporation deposition method in which a low-molecular-weight organic compound is deposited by evaporation via an evaporation deposition mask having an aperture pattern corresponding to a display element area.

A process of forming the organic EL element is, for example, as follows. To begin with, a first electrode is formed in each pixel. The area where the first electrode is formed corresponds to a display element area which contributes to light emission. A partition wall for isolation between pixels, which has a greater height (or a greater thickness) than the first electrode, is formed around the first electrode. Then, an evaporation deposition mask, which has an aperture pattern corresponding to the display element area, is disposed. In this state, a material source is deposited by evaporation via the evaporation deposition mask in a chamber for evaporation deposition. Thereby, an organic active layer is formed on the first electrode. The area where the material source is deposited is substantially equal in size to the aperture pattern, but it may become larger than the aperture pattern depending on the distance from the evaporation deposition surface, that is, the surface of the first electrode, to the evaporation deposition mask. The partition wall has a function of holding the evaporation deposition mask, keeping a fixed distance from the first electrode, and ensuring isolation from a display element area of another neighboring color pixel. Subsequently, a second electrode is formed so as to cover the organic active layer. This organic EL element emits light when an electric current is caused to flow between the first electrode and the second electrode, and the amount of emission light (or luminance) is adjusted by the amount of electric current.

In the case of applying the above-described mask evaporation deposition method, if there is a partial projection on the evaporation deposition mask, when the evaporation deposition mask is disposed close to, or put in contact with, the partition wall, the projection comes in contact with the partition wall and damages the upper surface of the partition wall (i.e. the surface on which the second electrode is disposed). A similar problem may also occur in the case where foreign matter is held between the evaporation deposition mask and the upper surface of the partition wall when the evaporation deposition mask is disposed. Such damage degrades the smoothness of the upper surface of the partition wall. Consequently, in the subsequently formed second electrode that is also disposed on the upper surface of the partition wall, a pinhole may form at the part of damage, leading to defective coverage over the partition wall.

To be more specific, the second electrode is normally formed so as to cover the entire partition wall. However, due to large irregularities at the part of damage on the upper surface of the partition wall, the upper surface of the partition wall may not sufficiently be covered with the second electrode. In other words, a part of the partition wall may be exposed from the second electrode.

In general, the partition wall is formed by patterning a resin material. In some cases, such a resin material contains some moisture permeability due to its nature. Consequently, there is a mode in which such a phenomenon occurs that moisture enters from a pinhole of the second electrode and diffuses into the partition wall. On the other hand, the organic EL element has such characteristics that degradation is accelerated by moisture or oxygen. In some case, the luminance of the organic EL element may deteriorate due to entrance of moisture, and light emission with normal luminance may be disabled with the passing of time. Specifically, in a pixel near the pinhole of the second electrode, the degradation of the organic EL element progresses quicker than in other pixels and non-uniformity may occur in luminance of emission light.

Besides, there is a mode in which such a phenomenon occurs that moisture or a gas component contained in respective parts, in particular, moisture contained in the resin material, may emanate from the pinhole of the second electrode to the outside. In this case, a normal pixel may gradually deteriorate with the passing of time while the degree of degradation of a pixel near the pinhole is small, and non-uniformity may occur in luminance of emission light.

### BRIEF SUMMARY OF THE INVENTION

The present invention has been made in consideration of the above-described problems, and the object of the invention is to provide a display device having good display quality, improved reliability and a long lifetime.

According to a first aspect of the present invention, there is provided a display device comprising: a first substrate which includes, in an active area of a wiring substrate, a self-luminous element provided in each of matrix-arrayed pixels, and a partition wall separating the pixels; and a second substrate which is disposed to be opposed to the self-luminous element side of the first substrate, wherein the first substrate further includes a support member which is isolated from the self-luminous element and has a predetermined height from a major surface of the wiring substrate.

According to a second aspect of the present invention, there is provided a display device comprising a substrate, a plurality of pixels which are arrayed in a matrix on the substrate, a partition wall which is disposed in a manner to divide the pixels and includes a resin layer, an organic active layer which is formed in each of the pixels in contact with the resin layer of the partition wall, and a support member which is formed to have a greater height from the substrate than the partition wall and includes a resin layer, wherein a path by resin material is cut off between an uppermost part of the resin layer which constitutes the support member and the resin layer which constitutes the partition wall.

The present invention can provide a display device having good display quality, improved reliability and a long lifetime.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 schematically shows the structure of an organic EL display device according to an embodiment of the present invention;

FIG. 2 shows an example of a display element and a pixel circuit, which constitute a pixel in the organic EL display device shown in FIG. 1;

FIG. 3 is a cross-sectional view that schematically shows the structure of an active area in a top-emission-type organic EL display device;

FIG. 4A is a cross-sectional view for describing a first structure example which is applicable to an organic EL display device according to Example 1 of the invention;

FIG. 4B is a view for describing an evaporation deposition step of an organic active layer in the first structure example shown in FIG. 4A;

FIG. 4C is a view for describing a step of forming a second electrode in the first structure example shown in FIG. 4A;

FIG. 4D is a plan view showing a state in which a pinhole forms in the second electrode on a support member in the first structure example shown in FIG. 4A;

FIG. 4E is a view for explaining an entrance path of moisture from the pinhole shown in FIG. 4D;

FIG. 5A is a plan view showing a state in which a pinhole forms in a second electrode on a partition wall in a comparative example;

FIG. 5B is a view for explaining an entrance path of moisture from the pinhole shown in FIG. 5A;

FIG. 6A is a cross-sectional view for describing a second structure example which is applicable to the organic EL display device according to Example 1 of the invention;

FIG. 6B is a cross-sectional view for describing another second structure example in Example 1 of the invention;

FIG. 6C is a cross-sectional view for describing still another second structure example in Example 1 of the invention;

FIG. 7 is a cross-sectional view for describing a third structure example which is applicable to the organic EL display device according to Example 1 of the invention;

FIG. 8A is a cross-sectional view for describing a first structure example which is applicable to an organic EL display device according to Example 2 of the invention;

FIG. 8B is a view for describing an evaporation deposition step of an organic active layer in the first structure example shown in FIG. 8A;

FIG. 8C is a view for describing a step of forming a second electrode in the first structure example shown in FIG. 8A;

FIG. 8D is a view for explaining an entrance path of moisture from a pinhole in a state in which the pinhole forms in the second electrode on a support member in the first structure example shown in FIG. 8A;

FIG. 9 is a cross-sectional view for describing a second structure example which is applicable to an organic EL display device according to Example 2 of the invention;

FIG. 10 is a cross-sectional view for describing a third structure example in Example 2 of the invention;

FIG. 11 is a cross-sectional view for describing a fourth structure example in Example 2 of the invention;

FIG. 12 is a plan view that schematically shows a support member which is disposed outside an active area;

FIG. 13 is a plan view that schematically shows support members which are disposed in respective pixels within an active area;

FIG. 14 is a plan view that schematically shows a support member which is disposed in every second pixel within an active area;

FIG. 15 is a plan view that schematically shows a support member which is disposed in every third pixel within an active area; and

FIG. 16 is a plan view that schematically shows a support member which is disposed in a manner to extend over a plurality of pixels.

### DETAILED DESCRIPTION OF THE INVENTION

A display device according to an embodiment of the present invention will now be described with reference to the accompanying drawings. In this embodiment, a self-luminous display device, for instance, a top-emission-type organic EL (electroluminescence) display device, is described as an example of the display device.

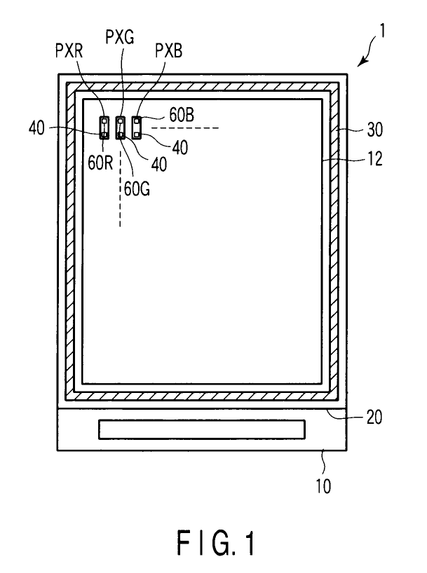

As shown in FIG. 1, an organic EL display device 1 includes an array substrate (first substrate) 10 and a sealing substrate (second substrate) 20 which is disposed to be opposed to the array substrate 10. The organic EL display device 1 with this structure has a substantially polygonal active area 12 which displays an image. The active area 12 is composed of a plurality of pixels PX which are arrayed in a matrix. In the example shown in FIG. 1, the active area 12 is formed in a rectangular shape.

FIG. 1 shows the organic EL display device 1 of a color display type, by way of example, and the active area 12 is composed of a plurality of kinds of color pixels, for instance, a red pixel PXR, a green pixel PXG and a blue pixel PXB corresponding to the three primary colors. The array substrate 10 and the sealing substrate 20 are attached by a sealing member 30 which is disposed in a frame shape so as to surround the active area 12.

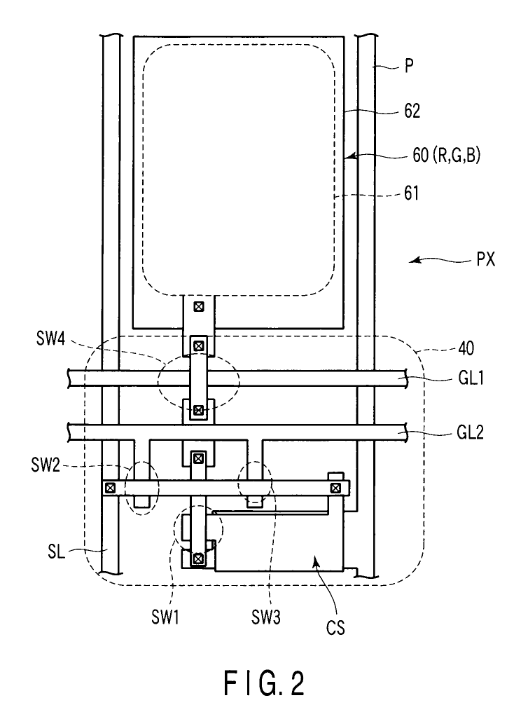

Each of the pixels PX (R, G, B) includes a pixel circuit 40 and a display element 60 which is driven and controlled by the pixel circuit 40. Although FIG. 2 shows an example of the pixel circuit 40, pixel circuits with other structures are, of course, applicable.

As shown in FIG. 2, the pixel circuit 40 is configured to include a first switch SW1, a second switch SW2, a third switch SW3, a fourth switch SW4 and a storage capacitance element CS. The first switch SW1 has a function of controlling the amount of electric current that is supplied to the display element 60. The second switch SW2 and the third switch SW3 function as a sample/hold switch. The fourth switch SW4 has a function of controlling the supply of driving current from the first switch SW1 to the display element 60. The storage capacitance element CS has a function of retaining a gate-source potential of the first switch SW1.

The first switch SW1 is connected between a power supply line P and the fourth switch SW4. The gate electrode of the first switch SW1 is connected to the second switch SW2. The fourth switch SW4 is connected between the first switch SW1 and the display element 60. The gate electrode of the fourth switch SW4 is connected to a first gate line GL1.

The second switch SW2 is connected between a signal line SL, on one hand, and the first switch SW1 and fourth switch SW4, on the other hand. The third switch SW3 is connected between the first switch SW1 and the second switch SW2. The gate electrodes of the second switch SW2 and third switch SW3 are connected to a second gate line GL2.

The first switch SW1, second switch SW2, third switch SW3 and fourth switch SW4 are composed of, for example, thin-film transistors, and their semiconductor layers are formed of polysilicon in this example.

In the case of this circuit structure, the second switch SW2 and the third switch SW3 are turned on, on the basis of the supply of an ON signal from the second gate line GL2. An electric current flows from the power supply line P to the first switch SW1 in accordance with the electric current flowing in the signal line SL, and the storage capacitance element CS is charged in accordance with the electric current flowing in the first switch SW1. In addition, on the basis of the supply of the ON signal from the first gate line GL1, the fourth switch SW4 is turned on, and an electric current corresponding to the capacitance stored in the storage capacitance element CS flows through the fourth switch SW4 via the first switch SW1. Thereby, a current corresponding to a predetermined luminance is supplied to the display element 60.

The display element 60 is composed of an organic EL element 60 (R, G, B) that is a self-luminous element. Specifically, the red pixel PXR includes an organic EL element 60R which mainly emits light corresponding to a red wavelength. The green pixel PXG includes an organic EL element 60G which mainly emits light corresponding to a green wavelength. The blue pixel PXB includes an organic EL element 60B which mainly emits light corresponding to a blue wavelength.

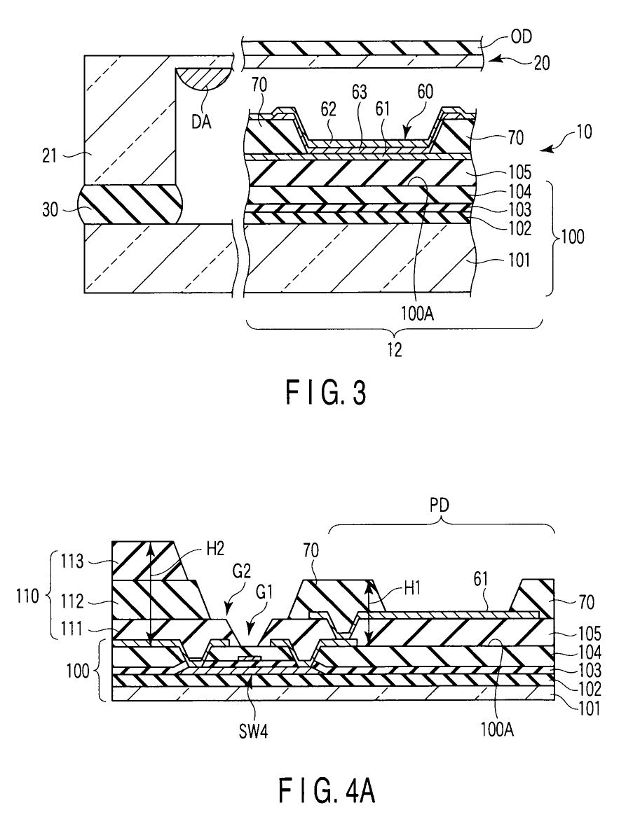

The respective kinds of organic EL elements 60 (R, G, B) have basically the same structure. For example, as shown in FIG. 3, the organic EL element 60 (R, G, B) is disposed on a wiring substrate 100. The wiring substrate 100 is configured such that an undercoat layer 102, a gate insulation film 103, an interlayer insulation film 104, as well as the pixel circuit 40 and various wiring lines, are provided on an insulative support substrate 101 such as a glass substrate or a plastic sheet. The surface of the interlayer insulation film 104 corresponds to a major surface 100A of the wiring substrate 100. The undercoat layer 102, gate insulation film 103 and interlayer insulation film 104 are formed of an inorganic material such as a silicon oxide film or a silicon nitride film. In the example shown in FIG. 3, an organic insulation film 105 is provided between the organic EL element 60 and the wiring substrate 100. The organic insulation film 105 is formed by patterning an insulative resin material, and the surface thereof is planarized.

The organic EL element 60 comprises a first electrode 61 which is disposed in an independent island shape in association with each pixel PX; a second electrode 62 which is disposed to be opposed to the first electrode 61 and is disposed common to a plurality of color pixels PX; and an organic active layer 63 which is held between the first electrode 61 and the second electrode 62.

The first electrode 61 is disposed on the organic insulation film 105 and functions as an anode. The first electrode 61 is connected to the fourth switch (driving transistor) SW4 via a contact hole which is formed in the organic insulation film 105. The first electrode 61 is composed of a single reflective layer that is formed of, e.g. aluminum or silver; a single transmissive layer that is formed of, e.g. indium tin oxide (ITO) or indium zinc oxide (IZO); or a multiplayer structure of a reflective layer and a transmissive layer. In the case of the top emission type, it is desirable that the first electrode 61 include a reflective layer.

The organic active layer 63 is disposed on the first electrode 61 and includes at least a light-emitting layer. The organic active layer 63 may include, for instance, in addition to the light-emitting layer, a hole transport layer, a hole injection layer, a blocking layer, an electron transport layer, an electron injection layer, and a buffer layer. Alternatively, the organic active layer 63 includes a layer in which these layers are functionally combined. The light-emitting layer is formed of an organic compound having a function of emitting red, green or blue light. The organic active layer 63 may be formed through a dry process such as an evaporation deposition process with use of a low-molecular-weight material.

The second electrode 62 is disposed so as to cover the organic active layer 63 and functions as a cathode. The second electrode 62 is connected to a second electrode power supply line (not shown) which is disposed around the active area 12 and supplies a common potential, which is a ground potential in this example. In the case of the top emission type, the second electrode is composed of a single transmissive layer, a single semi-transmissive layer, or a multilayer structure of a transmissive layer and a semi-transmissive layer.

The array substrate 10 includes, in the active area 12, partition walls 70 which isolate the pixels PX (R, G, B). The partition walls 70 are disposed in lattice shapes or in stripe shapes so as to divide the respective pixels and to cover peripheral edges of the first electrode 61. The partition wall 70 includes a resin layer which is formed of an insulative resin material. In this example, the partition walls 70 are formed by patterning a resin material. In addition, the partition walls 70, together with the organic active layer 63, are covered with the second electrode 62.

The sealing substrate 20 is disposed to be opposed to the organic EL element 60 of the array substrate 10. The sealing substrate 20 is attached to the array substrate 10 by the sealing member 30 that is coated on a peripheral portion 21 of the sealing substrate 20. Thereby, the organic EL element 60 is sealed in an airtight space. In the case of the top emission type, a desiccating agent DA is disposed on the inner surface of the sealing substrate 20 (i.e. on that surface of the sealing substrate 20, which faces the array substrate 10) between the peripheral portion 21 and the active area 12. In addition, it is preferable to dispose an optical element OD, such as a polarizer, on the outer surface of the sealing substrate 20 (i.e. that surface of the sealing substrate 20, which is opposite to the surface thereof on which the desiccating agent DA is disposed).

In the above-described organic EL display device, the array substrate 10 includes a support member which is isolated from the organic EL element 60 (or the display element area corresponding to the area where the first electrode 61 is disposed) and has a predetermined height from the major surface 100A of the wiring substrate 100. The structure of the support member will be described below in greater detail.

### EXAMPLE 1

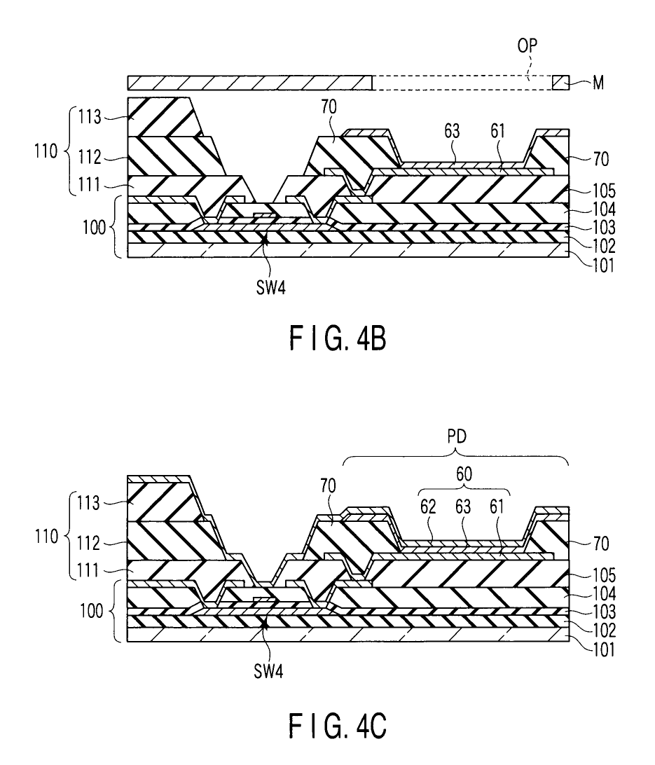

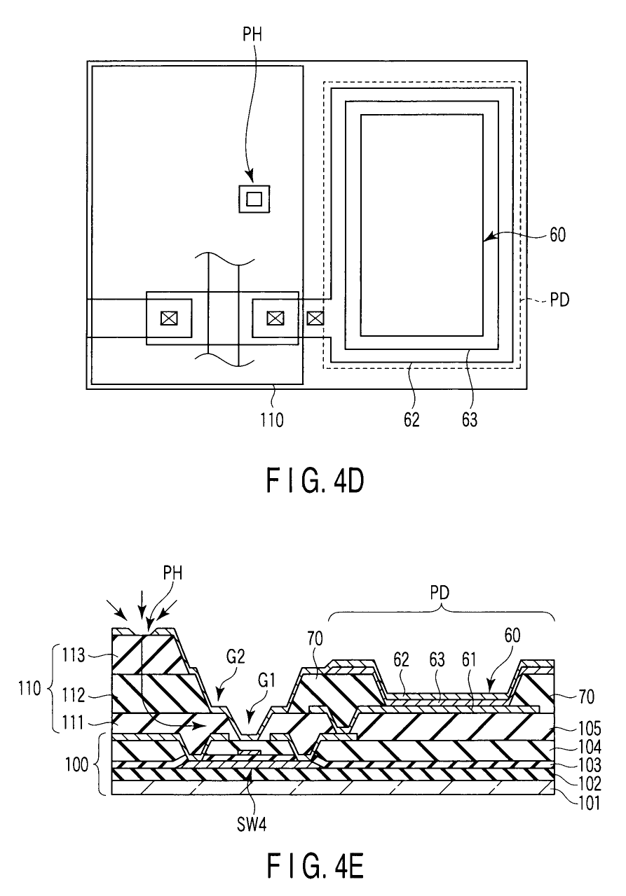

In an organic EL display device according to Example 1 of the present invention, as shown in FIG. 4A, a support member 110, which is disposed on the major surface 100A of the wiring substrate 100, has a height H2, which is greater than a height H1 from the major surface 100A to a top point (upper surface) 70T of the partition wall 70. The support member 110 includes at least one resin layer. The support member 110 according to a first structure example is composed of a multiplayer structure in which a plurality of layers are stacked.

Specifically, in the first structure example shown in FIG. 4A, the support member 110 comprises a first resin layer 111 which is disposed on the wiring substrate 100, a second resin layer 112 which is stacked on the first resin layer 111, and a third resin layer 113 which is stacked on the second resin layer 112.

The first resin layer 111 is a resin layer which is the same layer as the organic insulation film 105, and may be formed of the same resin material as the organic insulation film 105. The first resin layer 111 is formed at the same time as the organic insulation film 105, for example, by patterning a resin material layer which is formed on the wiring substrate 100. In addition, in the first resin layer 111, a groove G1 is formed between the organic EL element 60 (or display element region PD) and the support member 110. Specifically, by the patterning of the resin material, the first resin layer 111, which constitutes the support member 110, and the organic insulation film 105, which functions as an underlayer of the organic EL element 60, are formed at the same time, and the first resin layer 111 and the organic insulation film 105 are separated from each other.

The second resin layer 112 is a resin layer which is the same layer as the partition wall 70, and may be formed of the same resin material as the partition wall 70. The second resin layer 112 is formed at the same time as the partition wall 70, for example, by patterning a resin material layer which is formed on the organic insulation film 105 and the first resin layer 111. In addition, in the second resin layer 112, a groove G2 is formed between the organic EL element 60 (or display element region PD) and the support member 110. Specifically, by the patterning of the resin material, the second resin layer 112, which constitutes the support member 110, and the partition wall 70 are formed at the same time, and the second resin layer 112 and the partition wall 70 are separated from each other.

The third resin layer 113 may be formed by patterning a resin material layer which is formed on the second resin layer 112. The third resin layer 113 is disposed in an island shape on the second resin layer 112 that is separated from the partition wall 70.

The support member 110 of the first structure example is physically separated from the organic insulation film 105 and partition wall 70 by the grooves G1 and G2 which are formed in the first resin layer 111 and second resin layer 112, and can be isolated from the organic EL element 60 or display element region PD. The term “isolation” refers to the state in which the support member 110 is not connected to the organic EL element 60 or display element region PD via a layer of resin material. In other words, a path by resin material is cut off between the uppermost part of the resin layer which constitutes the support member 110 and the resin layer which constitutes the partition wall 70.

On the wiring substrate 100 having the above-described support member 110, the organic EL element 60 is formed by the following process. To start with, as shown in FIG. 4A, there is prepared a wiring substrate 100 including a support member 110 which is isolated from the display element region PD. Then, as shown in FIG. 4B, an evaporation deposition mask M, which has an aperture pattern OP corresponding to the display element region PD, is placed on the support member 110. A material including an organic compound having a light-emitting function is deposited by evaporation on the first electrode 61, and thus an organic active layer 63 is formed. The organic active layer 63, which is thus formed, is in contact with the partition wall 70 that is a resin layer. The evaporation deposition mask M, which is used here, is configured such that an aperture pattern is formed in a metallic base material or a base material having properties substantially equal to those of the metallic base material. Then, as shown in FIG. 4C, the evaporation deposition mask M is removed, and a second electrode 62 is formed on the organic active layer 63. By this process, the organic EL element 60 is formed.

In this forming process, the support member 110 has a greatest height H2 in the display element region PD, that is, a height H2 which is greater than a height H1 from the major surface 100A of the wiring substrate 100 to the upper surface 70T of the partition wall 70. Thus, even if the evaporation deposition mask M is placed in contact with the support member 110, the support member 110 supports the evaporation deposition mask M in the state in which the evaporation deposition mask M is spaced apart from the display element region PD. In other words, a space corresponding to a difference between the height H2 of the support member 110 and the height H1 of the display element region PD is formed between the upper surface 70T of the partition wall 70 and the evaporation deposition mask M.

Accordingly, the evaporation deposition mask M does not come in direct contact with the partition wall 70, and damage to the partition wall 70 can be prevented. Furthermore, even if the evaporation deposition mask M comes in contact with the support member 110 and damages the support member 110 and a pinhole forms in the second electrode 62 that covers the support member 110, there is no path of moisture, which is formed of resin material connecting the support member 110 and the organic EL element 60.

For example, as shown in FIG. 4D and FIG. 4E, assume that the support member 110 is damaged, and a pinhole PH forms in the second electrode 62. Moisture, which has entered via the pinhole PH, moves from the third resin layer 113 to the second resin layer 112 to the first resin layer 111 in the support member 110, but the movement of moisture to the organic EL element 60 side is prevented by the grooves G1 and G2. Needless to say, the movement of moisture, which is contained in resin material in the vicinity of the organic EL element 60, to the support member 110 is also prevented.

Specifically, in the organic EL element 60, even if the partition wall 70, which is formed of resin material, is in contact with the organic active layer 63, moisture which has entered from the support member 110 does not reach the partition wall 70, and degradation of the organic active layer 63 can be suppressed. In addition, even if the partition wall 70 contains moisture, the moisture does not reach the support member 110. Therefore, even the organic EL element 60 of the pixel, which is located near the pinhole PH, can maintain light emission characteristics which are substantially equal to those of organic EL elements of other pixels.

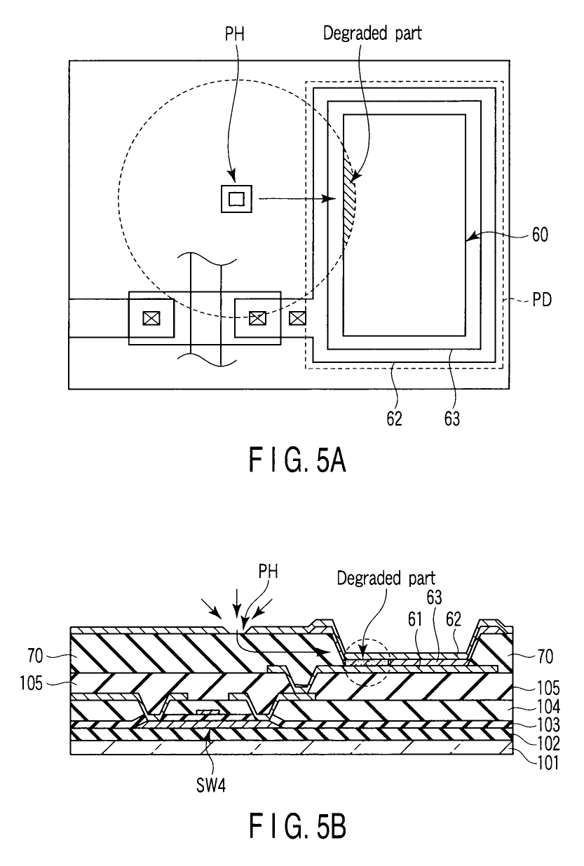

On the other hand, in a comparative example as shown in FIG. 5A and FIG. 5B, in a case where the partition wall 70 is damaged and a pinhole PH forms in the second electrode 62, moisture which has entered via the pinhole PH moves from the partition wall 70 to the organic EL element 60, and causes damage, in particular, to the organic active layer 63. Consequently, the organic EL element 60 deteriorates from a part thereof which is near the pinhole PH and, in some case, the light emission characteristics of this organic EL element 60 may become lower than those of organic EL elements of other pixels. On the other hand, moisture or the like, which is contained in the resin material in the vicinity of the organic EL element 60, may easily emanate from the pinhole PH to the outside. As a result, there is a case in which the degradation of the part of the organic EL element 60 near the pinhole PH does not easily progress, and this organic EL element 60 maintain better light emission characteristics than organic EL elements of other pixels.

As has been described above, according to Example 1, it is possible to suppress the movement of moisture, which has entered from the support member 110, to the organic EL element 60, and the movement of moisture, which has emanated from the resin material near the organic EL element 60, to the support member 110, and therefore it is possible to prevent a variation in light emission characteristics of the organic EL element 60 in a local pixel.

In the first structure example, the support member 110 is composed of the multilayer structure in which a plurality of resin layers are stacked. The invention, however, is not limited to this example, and the support member 110 may include an electrically conductive layer. In this case, the support member 110 should preferably include a layer which is the same layer as an insulation layer or an electrically conductive layer that is necessary for forming the organic EL element 60 in each pixel. Thereby, the number of process steps for forming the support member 110 does not greatly increase, and an increase in manufacturing cost can be suppressed.

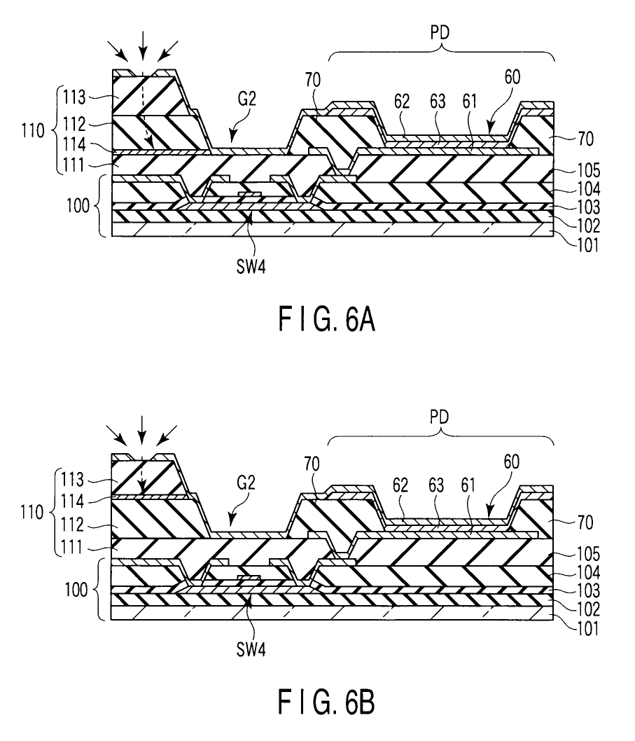

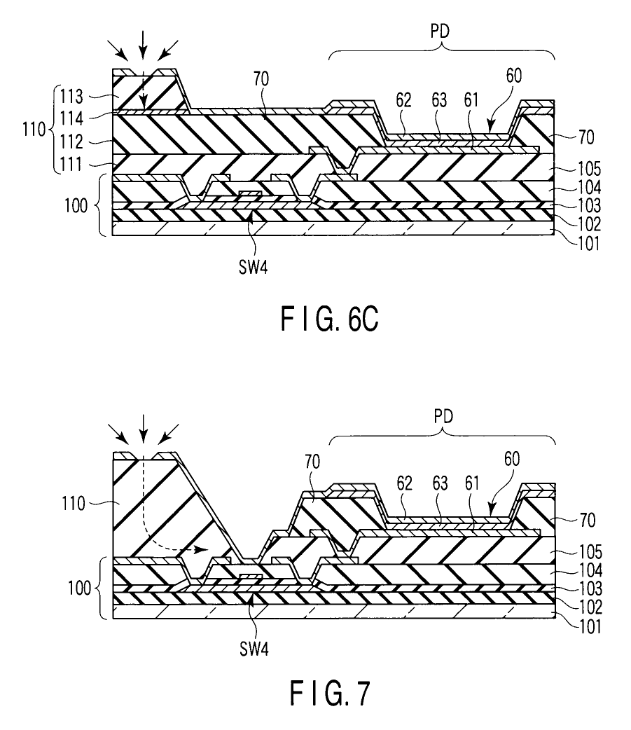

In a second structure example shown in FIG. 6A to FIG. 6C, the support member 110 comprises a first resin layer 111 which is disposed on the wiring substrate 100, a second resin layer 112 which is stacked on the first resin layer 111, and a third resin layer 113 which is stacked on the second resin layer 112. In addition, the support member 110 includes a waterproof layer 114 which is disposed at least between the first resin layer 111 and the second resin layer 112 or between the second resin layer 112 and the third resin layer 113.

In an example shown in FIG. 6A, the waterproof layer 114 is disposed between the first resin layer 111 and the second resin layer 112. In examples shown in FIG. 6B and FIG. 6C, the waterproof layer 114 is disposed between the second resin layer 112 and the third resin layer 113. The waterproof layer 114 may be formed by subjecting the surface of the first resin layer 111 or second resin layer 112 to a process of reducing moisture permeability, for example, by denaturing the surface of the first resin layer 111 or second resin layer 112, or may be formed independently of an inorganic material such as a low-water-permeability metallic film.

In the second structure example, the first resin layer 111 is a resin layer which is the same layer as the organic insulation film 105, and may be formed by patterning a resin material layer which is formed on the wiring substrate 100. In addition, the first resin layer 111 is formed integral with the organic insulation film 105 without a groove between the organic EL element 60 (or display element region PD) and the support member 110. In other words, the support member 110 and the organic EL element 60 (or display element region PD) are connected via a layer of resin material.

The second resin layer 112 is a resin layer which is the same layer as the partition wall 70, and may be formed by patterning a resin material layer which is formed on the first resin layer 111. In addition, in the examples shown in FIG. 6A and FIG. 6B, a groove G2 is formed in the second resin layer 112 between the organic EL element 60 (or display element region PD) and the support member 110. In other words, the second resin layer 112, which constitutes the support member 110, and the partition wall 70 are separated from each other.

On the other hand, in the example shown in FIG. 6C, the second resin layer 112 is formed integral with the partition wall 70 without a groove between the organic EL element 60 (or display element region PD) and the support member 110. In other words, the support member 110 and the organic EL element 60 (or display element region PD) are connected via a layer of resin material.

The third resin layer 113 may be formed by patterning a resin material layer which is formed on the second resin layer 112. The third resin layer 113 is disposed in an island shape on the second resin layer 112 that is separated from the partition wall 70.

According to the support member 110 of the above-described second structure example, as in the examples shown in FIG. 6B and FIG. 6C, the waterproof layer 114 is provided between the second resin layer 112 and the third resin layer 113 that is disposed in an island shape on the second resin layer 112. Thereby, the support member 110 can be isolated from the organic EL element 60 or display element region PD. In addition, as in the example of FIG. 6A, the support member 110 includes the waterproof layer 114 between the first resin layer 111 and the second resin layer 112, and the support member 110 can be isolated from the organic EL element 60 or display device region PD by the groove G2 that is formed in the second resin layer 112. In other words, a path by resin material is cut off between the uppermost part of the resin layer which constitutes the support member 110 and the resin layer which constitutes the partition wall 70. Therefore, the same advantageous effects as in the first structure example can be obtained.

In a third structure example shown in FIG. 7, the support member 110 is formed of a single resin layer which is disposed in an island shape on the wiring substrate 100. This support member 110 is formed in a process which is different from the process of forming the organic insulation film 105 or partition wall 70, and can be formed by patterning a resin material layer which is formed on the wiring layer 100.

The support member 110 of this third structure example is independently provided on the wiring substrate 100, and is physically separated from the organic insulation film 105 and the partition wall 70. Thus, the support member 110 can be isolated from the organic EL element 60 or display element region PD. Specifically, the support member 110 is not connected to the organic EL element 60 or display element region PD via a layer of resin material. In other words, a path by resin material is cut off between the uppermost part of the resin layer which constitutes the support member 110 and the resin layer which constitutes the partition wall 70. Therefore, the same advantageous effects as in the first structure example can be obtained.

In the above-described Example 1, in particular, as in the first structure example and second structure example, in the case where the support member 110 is formed of a multilayer structure of three layers, the third resin layer 113, which is disposed in an island shape on the second resin layer 112 that constitutes the support member 110, may be formed of a resin material having a lower water permeability than the second resin layer 112. In a case where the second resin layer 112 is formed of an acrylic resin material, the third resin layer 113 is formed of, for instance, polyimide. In addition, in the case where the support member 110 is formed of a single resin layer, as in the third structure example, the support member 110 may be formed of a low-water-permeability resin material such as polyimide. Besides, such a resin layer may be formed by selecting a material which hardly absorbs moisture, aside from the conditions for forming the display element region PD.

Thereby, without using the groove G1 or G2 or the waterproof layer 114, the support member 110 can be isolated from the organic EL element 60 or display element region PD.

### EXAMPLE 2

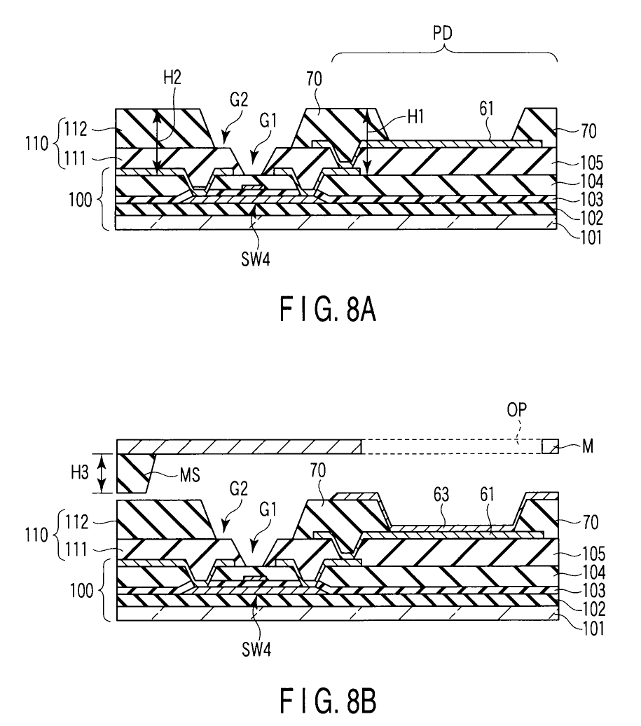

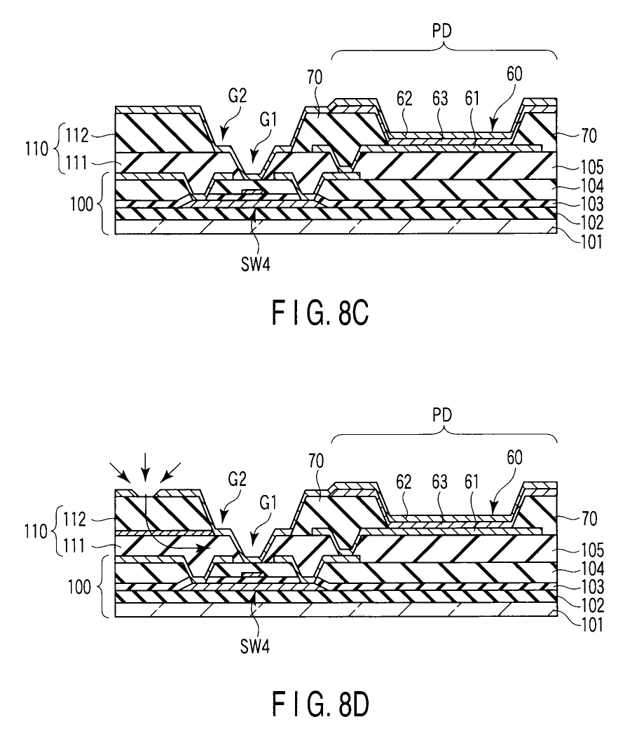

In an organic EL display device according to Example 2, as shown in FIG. 8A, a support member 110, which is disposed on the major surface 100A of the wiring substrate 100, has a height H2, which is equal to or less than a height H1 from the major surface 100A to a top point (upper surface) 70T of the partition wall 70. The support member 110 includes at least one resin layer. The support member 110 according to a first structure example is composed of a multiplayer structure in which a plurality of layers are stacked, and has a height H2 which is equal to a height H1 (H1=H2).

Specifically, in the first structure example shown in FIG. 8A, a support member 100 comprises a first resin layer 111 which is disposed on the wiring substrate 100, and a second resin layer 112 which is stacked on the first resin layer 111.

The first resin layer 111 and second resin layer 112 are structured like the first structure example of Example 1. Specifically, in the first resin layer 111, a groove G1 is formed between the organic EL element 60 (or display element region PD) and the support member 110. In the second resin layer 112, a groove G2 is formed between the organic EL element 60 (or display device region PD) and the support member 110.

The support member 110 of the first structure example is physically separated from the organic insulation film 105 and partition wall 70 by the grooves G1 and G2 which are formed in the first resin layer 111 and second resin layer 112, and can be isolated from the organic EL element 60 or display element region PD. In other words, a path by resin material is cut off between the uppermost part of the resin layer which constitutes the support member 110 and the resin layer which constitutes the partition wall 70.

On the wiring substrate 100 having the above-described support member 110, the organic EL element 60 is formed by the following process. To start with, as shown in FIG. 8A, there is prepared a wiring substrate 100 including a first electrode 61 and a support member 110 which is isolated from the display element region PD. Then, as shown in FIG. 8B, an evaporation deposition mask M, which has an aperture pattern OP corresponding to the display element region PD and has a spacer MS, is placed on the support member 110. A material including an organic compound having a light-emitting function is deposited by evaporation on the first electrode 61 via the evaporation deposition mask M, and thus an organic active layer 63 is formed. The organic active layer 63, which is thus formed, is in contact with the partition wall 70 that is a resin layer. Then, as shown in FIG. 8C, the evaporation deposition mask M is removed, and a second electrode 62 is formed on the organic active layer 63. By this process, the organic EL element 60 is formed.

In this forming process, the support member 110 has a greatest height H2 in the display element region PD, that is, a height H2 which is equal to or less than a height H1 from the major surface 100A of the wiring substrate 100 to the upper surface 70T of the partition wall 70. On the other hand, the evaporation deposition mask M has the spacer MS having a height H3 which is equal to or greater than a difference between the height H1 of the display element region PD and the height H2 of the support member 110.

Thus, when the spacer MS that is provided on the evaporation deposition mask M is placed in contact with the support member 110, the support member 110 supports the spacer MS of the evaporation deposition mask M in the state in which the spacer MS of the evaporation deposition mask M is spaced apart from the display element region PD. In other words, a space corresponding to the height of the spacer MS is formed between the upper surface 70T of the partition wall 70 and the evaporation deposition mask M.

Accordingly, the evaporation deposition mask M does not come in direct contact with the partition wall 70, and damage to the partition wall 70 can be prevented. Furthermore, even if the evaporation deposition mask M comes in contact with the support member 110 and damages the support member 110 and a pinhole forms in the second electrode 62 that covers the support member 110, there is no path of moisture, which is formed of resin material connecting the support member 110 and the organic EL element 60.

For example, as shown in FIG. 8D, assume that the support member 110 is damaged, and a pinhole PH forms in the second electrode 62. Moisture, which has entered via the pinhole PH, moves from the second resin layer 112 to the first resin layer 111 in the support member 110, but the movement of moisture to the organic EL element 60 side is prevented by the grooves G1 and G2. Needless to say, the movement of moisture, which is contained in resin material in the vicinity of the organic EL element 60, to the support member 110 is also prevented. Therefore, even the organic EL element 60 of the pixel, which is located near the pinhole PH, can maintain light emission characteristics which are substantially equal to those of organic EL elements of other pixels.

As has been described above, according to Example 2, like Example 1, it is possible to suppress the movement of moisture, which has entered from the support member 110, to the organic EL element 60, and the movement of moisture, which has emanated from the resin material near the organic EL element 60, to the support member 110, and therefore it is possible to prevent a variation in light emission characteristics of the organic EL element 60 in a local pixel.

In the first structure example, the support member 110 is composed of the multilayer structure in which a plurality of resin layers are stacked. The invention, however, is not limited to this example, and the support member 110 may include an electrically conductive layer. In this case, the support member 110 should preferably include a layer which is the same layer as an insulation layer or an electrically conductive layer that is necessary for forming the organic EL element 60 in each pixel. Thereby, the number of process steps for forming the support member 110 does not greatly increase, and an increase in manufacturing cost can be suppressed.

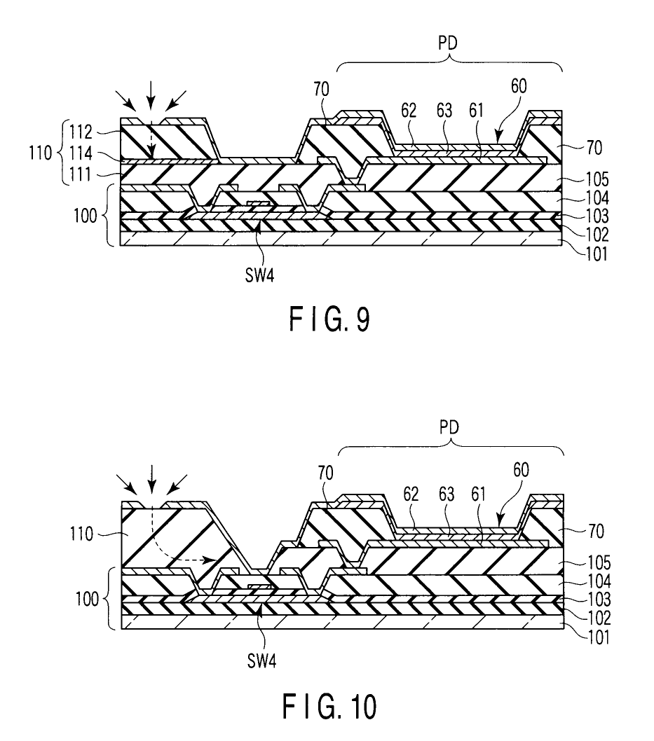

In a second structure example shown in FIG. 9, the support member 110 comprises a first resin layer 111 which is disposed on the wiring substrate 100 and a second resin layer 112 which is stacked on the first resin layer 111. In addition, the support member 110 includes a waterproof layer 114 which is disposed between the first resin layer 111 and the second resin layer 112.

The first resin layer 111, second resin layer 112 and waterproof layer 114 are structured like the second structure example of Example 1. Specifically, a groove G2 is formed in the second resin layer 112 between the organic EL element 60 (or display element region PD) and the support member 110.

According to the support member 110 of the above-described second structure example, as in the example shown in FIG. 6A, the waterproof layer 114 is provided between the first resin layer 111 and the second resin layer 112. In addition, the support member 110 can be isolated from the organic EL element 60 or display device region PD by the groove G2 that is formed in the second resin layer 112. In other words, a path by resin material is cut off between the uppermost part of the resin layer which constitutes the support member 110 and the resin layer which constitutes the partition wall 70. Therefore, the same advantageous effects as in the first structure example can be obtained.

In a third structure example shown in FIG. 10, the support member 110 is formed of a single resin layer which is disposed in an island shape on the wiring substrate 100. This support member 110 can be formed by patterning a resin material layer which is formed on the wiring layer 100.

The support member 110 of this third structure example is independently provided on the wiring substrate 100, and is physically separated from the organic insulation film 105 and the partition wall 70. Thus, the support member 110 can be isolated from the organic EL element 60 or display element region PD. Specifically, the support member 110 is not connected to the organic EL element 60 or display element region PD via a layer of resin material. In other words, a path by resin material is cut off between the uppermost part of the resin layer which constitutes the support member 110 and the resin layer which constitutes the partition wall 70. Therefore, the same advantageous effects as in the first structure example can be obtained.

In the above-described Example 2, in particular, as in the first structure example and second structure example, in a case where the support member 110 is formed of a multilayer structure of two layers, the second resin layer 112, which is disposed in an island shape on the first resin layer 111 that constitutes the support member 110, may be formed of a resin material having a lower water permeability than the first resin layer 111. In a case where the first resin layer 111 is formed of an acrylic resin material, the second resin layer 112 is formed of, for instance, polyimide. In addition, in the case where the support member 110 is formed of a single resin layer, as in the third structure example, the support member 110 may be formed of a low-water-permeability resin material such as polyimide.

Thereby, without using the groove G1 or G2 or the waterproof layer 114, the support member 110 can be isolated from the organic EL element 60 or display element region PD.

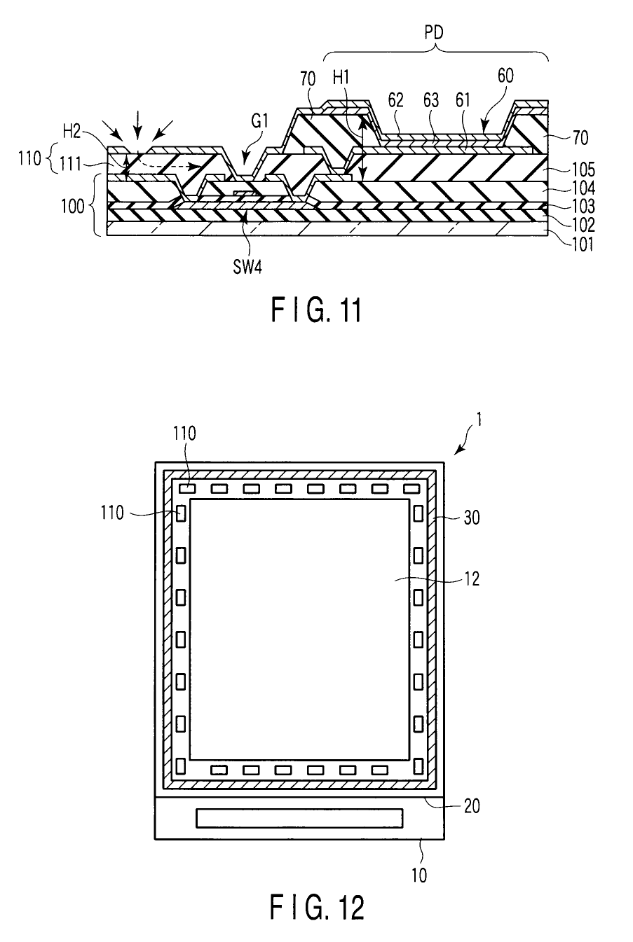

In the above-described Example 2, the support member 110 in each of the first to third structure examples has the height H2 which is equal to the height Hi (Hi=H2). In a fourth structure example shown in FIG. 11, the support member 110 has a height H2 which is lower than the height Hi (H1>H2). This support member 110 is composed of a first resin layer 111 which is disposed on the wiring substrate 100. The first resin layer 111 is a resin layer which is the same layer as the organic insulation film 105, and can be formed by patterning a resin material layer which is formed on the wiring substrate 100. A groove G1 is formed in the first resin layer 111 between the organic EL element 60 (or display element region PD) and the support member 110. In other words, the first resin layer 111 and the organic insulation film 105 are separated from each other. Therefore, the support member 110 can be isolated from the organic EL element 60 or the display element region PD.

As regards the fourth structure example, contact between the evaporation deposition mask M and the display element region PD can be prevented by using an evaporation deposition mask M with a spacer MS having a height which is greater than a difference between the height H1 and the height H2.

[symbol]

Patterns of Disposition of Support Members

[symbol]

As shown in FIG. 12, the support member 110 may be disposed in an inside area which is surrounded by the sealing member 30 and is located outside the active area 12. Since the area outside the active area 12 is hardly affected by restrictions of layout of pixels, support members 110 each having a relatively large size can easily be formed. In addition, since the support members 110 are sufficiently spaced apart from the pixels, even if the support members 110 are damaged, the damage hardly affects the organic EL elements 60 of the respective pixels.

On the other hand, the support members 110 may be disposed in the active area 12. Although it is difficult to form large-sized support members 110 in the active area 12, it is easy to form small-sized support members 110 with a necessary density. The support members 110 and the organic EL elements 60 can be isolated by surrounding the support members 110 by grooves, or surrounding the organic EL elements 60 by grooves, or by making the support members 110 include waterproof layers or low-water-permeability resin material layers. Therefore, even if the support members 110 are damaged, the influence on the organic EL elements 60 of the pixels is small.

As shown in FIG. 2, each of the pixels PX includes a display element area in which the organic EL element 60 is disposed, and an area other than the display element area, namely, in this example, a circuit area in which the pixel circuit 40 is disposed. In the case where the support members 110 are disposed in the active area 12, such circuit areas are usable as areas in which the support members 110 are disposed.

In the case of the top emission type, the display element area can also be used for the circuit area, and the display element area with a larger size can be secured. In this case, if a circuit area which does not overlap the display element area or an area in which various wiring lines are formed is regarded as a circuit area, this technique does not depart from the scope of the invention. Specifically, in the case where the support members are disposed in the active area 12, the support members 110 may be disposed by making use of the areas other than the display element areas. In consideration of the process, it is possible to adjust the positions of overlapping parts between the parts where the support members 110 are disposed and the various switches and various wiring lines.

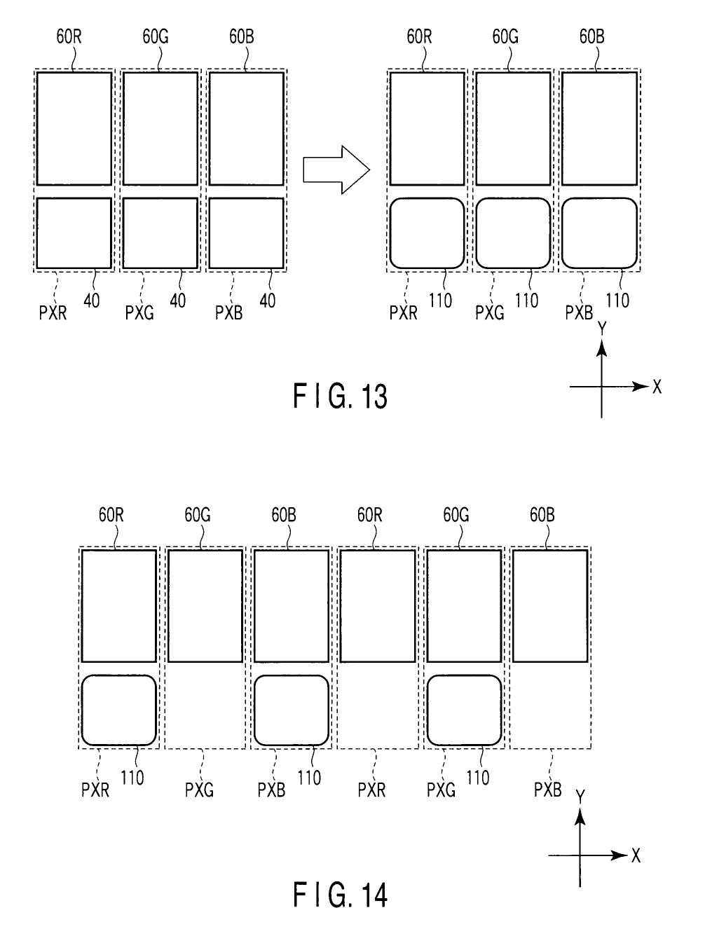

The support member 110 may be disposed in each pixel PX. In an example shown in FIG. 13, a red pixel PXR, a green pixel PXG and a blue pixel PXB are arranged in a row direction X. Each pixel PX (R, G, B) includes a pixel circuit 40. The pixel circuits 40 of the respective pixels PX (R, G, B) are arranged in the row direction X. Areas extending in the row direction X, in which the pixel circuits 40 are arranged, correspond to circuit regions in which the support members 110 can be disposed. In this example, the support members 110 are disposed so as to overlap the pixel circuits 40 of the respective pixels PX (R, G, B).

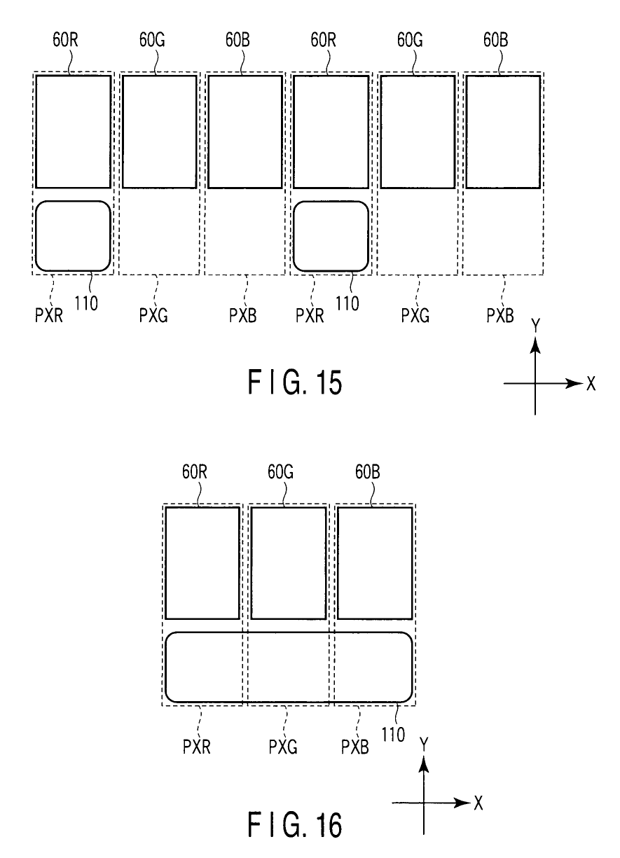

Alternatively, the support member 110 may be disposed in every n-th pixel (n: a positive integer). In an example shown in FIG. 14, the red pixel PXR, green pixel PXG and blue pixel PXB are repeatedly arranged in the named order in the row direction X. In this example, the support member 110 is disposed in every second pixel in the row direction X. In an example shown in FIG. 15, the support member 110 is disposed in every third pixel in the row direction X. In this case, similarly in the column direction Y, the support member 110 may be disposed in every n-th pixel. In the examples shown in FIG. 14 and FIG. 15, the support members 110 are disposed with regularity. However, with a certain degree of irregularity, the support members 110 may be disposed at random at least in some parts in the circuit areas.

Alternatively, the support member 110 may be disposed so as to extend over a plurality of pixels. In an example shown in FIG. 16, the red pixel PXR, green pixel PXG and blue pixel PXB are arranged in the row direction X. In this example, the support member 110 extends in the row direction X and is disposed with a length of three pixels.

In the meantime, a support member 110 having a length corresponding to two pixels may be disposed in every n-th pixel, or at random. A support member 110 having a greater length than in the example of FIG. 16 may be disposed. In this case, the support member 110 may be disposed over various wiring lines. Besides, a support member 110 having a length corresponding to one pixel may be disposed so as to lie over two pixels.

The support member 110 is formed in a substantially conical shape, a substantially columnar shape, a substantially pyramidal shape or a substantially prismatic shape. Furthermore, the support member 110 may have such a plan-view shape (i.e. a cross section in a plane parallel to the major surface of the wiring substrate) as an elliptic shape, a straight shape or a curved shape.

The height H2 of the support member 110 having the above-described structure is so set that a gap forms between the evaporation deposition mask M and the upper surface 70T of the partition wall 70 when the evaporation deposition mask M is placed on the support member 110. For example, in Example 1, the evaporation deposition mask M is held by the support member 110, and a gap is provided between the evaporation deposition mask M and the upper surface 70T of the partition wall 70. In Example 2, the evaporation deposition mask M is held by the support member 110 via the spacer MS of the evaporation deposition mask M, and a gap is provided between the evaporation deposition mask M and the upper surface 70T of the partition wall 70.

At this time, the evaporation deposition mask M becomes closer to the partition wall 70 by a degree corresponding to bending of the evaporation deposition mask M. However, the height and disposition of the support member 110, the height and disposition of the spacer MS and the thickness and material of the evaporation deposition mask M may be chosen so as to keep the amount of bending at 1 μm or less. If the thickness of the evaporation deposition mask M is about 100 μm to 500 μm, the support members 110 may be disposed with an interval of about 100 μm to 500 μm so that the amount of bending can be kept at 1 μm or less. Thus, if the size of one side of the set (RGB set) of the red pixel, green pixel and blue pixel is about 200 μm, the support member 10 having a height of about 1 μm may be disposed in association with each RGB set, and this is sufficiently effective.

It is possible to adjust the amount of the gap between the evaporation deposition mask and the partition wall by statistically considering the size of foreign matter such as a projection (burr) on the evaporation deposition mask or foreign matter on the upper surface of the partition wall. However, if the amount of the gap is set to be excessively large, it is possible that such a color mixing phenomenon may occur that organic active layers, which are to be selectively colored in association with color pixels, may be mixed. Therefore, the gap should preferably be set at about 1 μm or less.

As has been described above, according to the present examples, the support member which supports the evaporation deposition mask is provided so as to prevent the evaporation deposition mask that is used from coming in contact with the partition wall of the display device area in the evaporation deposition step of the process of forming the organic EL element. The support member is structured such that the path of moisture diffusion is cut off from the surrounding of the organic EL element.

The support member can be formed by a method of forming at least a part of the partition wall in the same fabrication step as the formation of the partition wall, or by a method of independently disposing the support member. Since the processability required for the support member and that for the partition wall are different, the support member may be formed by choosing a material with low moisture permeability. Furthermore, the support member may be formed to include a waterproof layer.

The damage by the evaporation deposition mask occurs only to the support member. However, since moisture, which permeates and diffuses from the damaged part, does not reach the organic EL element, the acceleration of degradation due to moisture can be suppressed. Thus, when the organic EL elements are used for the display device, it is possible to prevent the luminance of organic EL elements of some pixels from degrading earlier than the luminance of the entire display device with the passing of time, which leads to a non-light-emission state (dark point). In addition, since moisture, which is contained in the vicinity of the organic EL element, does not emanate from the damaged part, it is possible to prevent, when the organic EL elements are used for the display device, the luminance of organic EL elements of some pixels from degrading earlier than the luminance of the entire display device with the passing of time, which leads to degradation in display balance.

As has been described above, the damage to the partition wall due to a projection or foreign matter on the evaporation deposition mask can be suppressed, and the occurrence of a defect (e.g. pinhole) in the second electrode or surface protection layer due to the damage can be prevented. Further, degradation of a local organic EL element due to the effect of moisture can be prevented. Therefore, it is possible to provide a display device which can suppress lowering of luminance of a pixel or non-lighting of a pixel with the passing of time, can prevent the occurrence of a phenomenon in which the display device is rendered non-usable due to the occurrence of many such similar pixels, and thus can have high reliability.

The present invention is not limited directly to the above-described embodiments. In practice, the structural elements can be modified and embodied without departing from the spirit of the invention. Various inventions can be made by properly combining the structural elements disclosed in the embodiments. For example, some structural elements may be omitted from all the structural elements disclosed in the embodiments. Furthermore, structural elements in different embodiments may properly be combined.

For example, in the above-described embodiments, the top-emission-type organic EL display devices have been exemplified. However, the above-described structures can be adopted in bottom-emission-type organic EL display devices.

What is claimed is:

1. A display device comprising:
a first substrate which includes, in an active area of a wiring substrate, a self-luminous element provided in each of matrix-arrayed pixels, and a partition wall separating the pixels; and
a second substrate which is disposed to be opposed to the self-luminous element side of the first substrate,
wherein the first substrate further includes a support member which is isolated from the self-luminous element and has a predetermined height from a major surface of the wiring substrate.

2. The display device according to claim 1, wherein the support member is composed of a single resin layer.

3. The display device according to claim 1, wherein the support member is composed of a multilayer structure in which a plurality of layers are stacked.

4. The display device according to claim 3, wherein the support member includes at least a layer which is the same layer as the partition wall.

5. The display device according to claim 4, wherein the support member includes a resin layer having a lower moisture permeability than the partition wall.

6. The display device according to claim 3, wherein the support member includes a waterproof layer.

7. The display device according to claim 1, wherein the support member has a height which is greater than a height from the major surface of the wiring substrate to a top point of the partition wall.

8. The display device according to claim 7, wherein the support member is composed of a first resin layer which is disposed on the wiring substrate, a second resin layer which is stacked on the first resin layer and is a layer that is the same layer as the partition wall, and a third resin layer which is stacked on the second resin layer, and
a groove is formed in the first resin layer and the second resin layer between the self-luminous element and the support member.

9. The display device according to claim 7, wherein the support member is composed of a first resin layer which is disposed on the wiring substrate, a second resin layer which is stacked on the first resin layer and is a layer that is the same layer as the partition wall, a third resin layer which is stacked on the second resin layer, and a waterproof layer which is disposed at least between the first resin layer and the second resin layer or between the second resin layer and the third resin layer.

10. The display device according to claim 9, wherein a groove is formed in the second resin layer between the self-luminous element and the support member.

11. The display device according to claim 7, wherein the support member is composed of a first resin layer which is disposed on the wiring substrate, a second resin layer which is stacked on the first resin layer and is a layer that is the same layer as the partition wall, and a third resin layer which is stacked on the second resin layer, and
the third resin layer is formed of a resin material having a lower moisture permeability than the second resin layer.

12. The display device according to claim 1, wherein the support member has a height which is equal to or less than a height from the major surface of the wiring substrate to a top point of the partition wall.

13. The display device according to claim 12, wherein the support member is composed of a first resin layer which is disposed on the wiring substrate, and a second resin layer which is stacked on the first resin layer and is a layer that is the same layer as the partition wall, and
a groove is formed in the first resin layer and the second resin layer between the self-luminous element and the support member.

14. The display device according to claim 12, wherein the support member is composed of a first resin layer which is disposed on the wiring substrate, a second resin layer which is stacked on the first resin layer and is a layer that is the same layer as the partition wall, and a waterproof layer which is disposed between the first resin layer and the second resin layer.

15. The display device according to claim 14, wherein a groove is formed in the second resin layer between the self-luminous element and the support member.

16. The display device according to claim 12, wherein the support member is composed of a first resin layer which is disposed on the wiring substrate, and
a groove is formed in the first resin layer between the self-luminous element and the support member.

17. A display device comprising a substrate, a plurality of pixels which are arrayed in a matrix on the substrate, a partition wall which is disposed in a manner to divide the pixels and includes a resin layer, an organic active layer which is formed in each of the pixels in contact with the resin layer of the partition wall, and a support member which is formed to have a greater height from the substrate than the partition wall and includes a resin layer,
wherein a path by resin material is cut off between an uppermost part of the resin layer which constitutes the support member and the resin layer which constitutes the partition wall.

18. The display device according to claim 17, wherein a groove is formed between the partition wall and the support member.

19. The display device according to claim 17, wherein a waterproof layer is disposed under the resin layer which constitutes the support member.
